(19) United States
(12) Patent Application Publication
(10) Pub. No.: US 2002/0038870 A1
(43) Pub. Date: Apr. 4, 2002

(54) Nitride-based semiconductor element and method of preparing nitride-based semiconductor

(75) Inventors: Tatsuya Kunisato, Osaka (JP); Hiroki Ohbo, Osaka (JP); Nobuhiko Hayashi, Osaka (JP); Takashi Kano, Osaka (JP)

Correspondence Address: McDERMOTT, WILL & EMERY, 600 13th Street, N.W., Washington, DC, 20005-3096, US

(73) Assignee: SANYO ELECTRIC CO., LTD.

(21) Appl. No.: 09/968,886

(22) Filed: Oct. 3, 2001

(30) Foreign Application Priority Data
Oct. 4, 2000 (JP) JP2000-304809
Dec. 25, 2000 (JP) JP2000-392946

(51) Int. Cl. H01L 27/15

(52) U.S. Cl. 257/85

(57) ABSTRACT

A method of preparing a nitride semiconductor capable of forming a nitride-based semiconductor layer having a small number of dislocations as well as a small number of crystal defects resulting from desorption with excellent crystallinity on the upper surface of a substrate through a small number of growth steps is proposed. The method of preparing a nitride-based semiconductor comprises steps of forming a mask layer on the upper surface of a substrate to partially expose the upper surface of the substrate, forming a buffer layer on the exposed part of the upper surface of the substrate and the upper surface of the mask layer and thereafter growing a nitride-based semiconductor layer. Thus, the outermost growth surface of the nitride-based semiconductor layer laterally grown on the mask layer does not come into contact with the mask layer. Therefore, desorption hardly takes place from the outermost growth surface of the nitride-based semiconductor layer, whereby a nitride-based semiconductor layer having a small number of defects is formed. Further, the mask layer is directly formed on the substrate, whereby the number of growth steps for the nitride-based semiconductor layer is reduced.

### BACKGROUND OF THE INVENTION

1. Field of the Invention

The present invention relates to a nitride-based semiconductor element and a method of preparing a nitride-based semiconductor, and more specifically, it relates to a nitride-based semiconductor element having a compound semiconductor layer consisting of a group III-V nitride-based semiconductor (hereinafter referred to as a nitride-based semiconductor) such as GaN (gallium nitride), AlN (aluminum nitride), InN (indium nitride), BN (boron nitride) or TlN (thallium nitride) or a mixed crystal thereof and a group III-V nitride-based semiconductor such as a mixed crystal of any combination of the aforementioned nitrides containing at least one element of As, P and Sb and a method of preparing a nitride-based semiconductor.

1. Description of the Prior Art

Recently, a semiconductor element utilizing a GaN-based compound semiconductor is actively developed as a semiconductor element employed for a semiconductor light emitting device such as a light emitting diode or an electronic element such as a transistor. In order to fabricate such a GaN-based semiconductor element, a GaN-based semiconductor layer is epitaxially grown on a substrate consisting of sapphire, SiC, Si or GaAs since it is difficult to fabricate a substrate consisting of GaN.

In this case, the GaN-based semiconductor layer grown on the substrate of sapphire or the like has threading dislocations (lattice defects) vertically extending from the substrate due to the difference between the lattice constants of sapphire or the like, forming the substrate, and GaN. The dislocation density is about 10⁹ cm⁻². Such dislocations in the GaN-based semiconductor layer result in deterioration of the element characteristics of the semiconductor element and reduction of reliability.

In general, epitaxial lateral overgrowth (ELO) is proposed as a method of reducing the number of dislocations in the aforementioned GaN-based semiconductor layer. This epitaxial lateral overgrowth is disclosed in Journal of Solid State Physics and Applications Division of the Japan Society of Applied Physics, Vol. 4 (1998), pp. 53 to 58 and pp. 210 to 215, or, Jpn. J. Appl. Phys. Vol. 36 (1997) pp. L899-L902 for example.

FIGS. 10 to 12 are sectional views for illustrating a conventional method of preparing a nitride-based semiconductor employing epitaxial lateral overgrowth. The conventional method of preparing a nitride-based semiconductor employing epitaxial lateral overgrowth is now described with reference to FIGS. 10 to 12.

First, an AlGaN buffer layer 102 having a thickness of several 10 nm is formed on the C (0001) plane of a sapphire substrate 101, and a first GaN layer 103 of GaN having a thickness of 3 to 4 μm is formed on the AlGaN buffer layer 102. Further, striped (elongated) mask layers 104 of SiO₂ are formed on the first GaN layer 103 as epitaxial growth masks.

Then, re-growth is performed through the epitaxial growth mask layers 104, thereby growing second GaN layers 105 of GaN having a thickness of at least 10 μm. GaN is hardly grown on the mask layers 104, and hence the second GaN layers 105 are selectively grown on upper surface portions of the first GaN layer 103 exposed between the adjacent ones of the mask layers 104 in the initial stage of the growth. In this case, the second GaN layers 105 are grown along arrow Y (c-axis direction) in FIG. 11 on the exposed upper surface portions of the first GaN layer 103. Thus, the second GaN layers 105 having a facet structure with triangular sections are grown on the exposed upper surface portions of the first GaN layer 103, as shown in FIG. 11.

When the growth of the second GaN layers 105 further progresses on the upper surface portions of the first GaN layer 103, the second GaN layers 105 are grown also along arrow X (lateral direction) in FIG. 11. The second GaN layers 105 are formed also on the mask layers 104 due to such lateral growth.

When further grown in the lateral direction, the second GaN layers 105 of the facet structure coalesce into a continuous film, as shown in FIG. 12. Thus, a second GaN layer 105 having a flat upper surface is defined. The number of threading dislocations is reduced in the vicinity of the planarized surface of the second GaN layer 105 formed in the aforementioned manner.

According to the conventional method of preparing a nitride-based semiconductor, as hereinabove described, the number of threading dislocations in the second GaN layer 105 can be reduced by epitaxially laterally growing the second GaN layer 105. A nitride-based semiconductor layer having excellent crystallinity can be formed on the sapphire substrate 101 by forming a nitride-based semiconductor layer (not shown) on such a second GaN layer 105 having a small number of dislocations.

In the aforementioned conventional method of preparing a nitride-based semiconductor employing epitaxial lateral overgrowth, however, the mask layers 104 are formed after forming the first GaN layer 103 on the sapphire substrate 101, followed by formation of the second GaN layers 105. Therefore, two steps of growing GaN layers, i.e., the first and second GaN layers 103 and 105, are required for obtaining a nitride-based semiconductor layer having excellent crystallinity. Consequently, the fabrication process is disadvantageously complicated in the conventional method employing epitaxial lateral overgrowth.

In the conventional method employing epitaxial lateral overgrowth, further, the surface of the first GaN layer 103 may be contaminated in the step of forming the mask layers 104. In this case, the second GaN layers 105 cannot be excellently formed on the contaminated surface of the first GaN layer 103.

In addition, the aforementioned conventional method employing epitaxial lateral overgrowth requires two types of GaN layers, i.e., the first and second GaN layers 103 and 105, and hence the total thickness of the layers formed on the sapphire substrate 101 is so increased that the wafer is disadvantageously remarkably bowing.

In order to solve the aforementioned problems, a method of forming a GaN layer having a small number of dislocations through single growth is proposed in relation to the method employing epitaxial lateral overgrowth. This method is disclosed in Japanese Patent Laying-Open No. 2000-21789, for example. According to this method, an SiO₂ mask is formed on a sapphire substrate followed by formation of a low-temperature growth GaN buffer layer and a high-temperature growth GaN layer, thereby forming a GaN layer having a small number of dislocations through single growth.

According to this method, the GaN layer may not be formed before formation of the mask layer, and hence it is possible to solve the aforementioned problem of contamination of the GaN layer located under the mask layer and the problem of the large total thickness of the layers formed on the substrate resulting in remarkable bowing of the wafer. Further, the GaN layer is formed through single growth, whereby a nitride-based semiconductor layer having a small number of dislocations can be formed through a small number of growth steps. Thus, the fabrication process is not complicated.

In the aforementioned conventional proposed method, however, the low-temperature growth GaN buffer layer is formed only in an opening of the SiO₂ mask and not on the upper surface of the SiO₂ mask. When the high-temperature growth GaN layer is laterally grown, therefore, the outermost growth surface of the high-temperature growth GaN layer comes into contact with the upper surface of the mask, to increase desorption from the outermost growth surface of the high-temperature growth GaN layer on this contact portion. Such increased desorption result in new crystal defects, to disadvantageously increase the number of defects in the GaN layer.

In the aforementioned conventional proposed method, further, oxygen atoms contained in SiO₂ forming the mask appear on the upper surface of the grown GaN layer. When a nitride-based light emitting device is formed on the GaN layer serving as an underlayer, therefore, the light emitting device cannot excellently emit light.

Japanese Patent Laying-Open No. 10-312971 (1998) also describes a technique of directly forming an SiO₂ mask on a substrate and thereafter forming a GaN layer having a small number of dislocations by single epitaxial lateral overgrowth with reference to FIG. 4, similarly to the aforementioned Japanese Patent Laying-Open No. 2000-21789. In the technique disclosed in Japanese Patent Laying-Open No. 10-312971, however, no buffer layer is formed on the upper surface of the SiO₂ mask and hence the outermost growth surface of the laterally grown GaN layer comes into contact with the upper surface of the mask layer, similarly to the aforementioned Japanese Patent Laying-Open No. 2000-21789. Therefore, desorption from the outermost growth surface of the GaN layer is increased in this contact portion. Thus, new crystal defects are caused to result in a large number of defects in the GaN layer.

In the prior art, as hereinabove described, it is difficult to form a nitride-based semiconductor layer having a small number of crystal defects resulting from desorption, although a nitride-based semiconductor layer having a small number of dislocations can be formed through a small number of growth steps.

### SUMMARY OF THE INVENTION

An object of the present invention is to provide a method of preparing a nitride-based semiconductor capable of forming a nitride-based semiconductor layer having a small number of dislocations and a small number of crystal defects resulting from desorption through a small number of growth steps.

Another object of the present invention is to provide a nitride-based semiconductor element having excellent element characteristics, including a nitride-based semiconductor layer having a small number of dislocations and a small number of crystal defects resulting from desorption.

A method of preparing a nitride-based semiconductor according to an aspect of the present invention comprises steps of forming a mask layer on the upper surface of a substrate to partially expose the upper surface of the substrate, forming a buffer layer on the exposed part of the upper surface of the substrate and the upper surface of the mask layer, and thereafter growing a nitride-based semiconductor layer.

In the method of preparing a nitride semiconductor according to the aforementioned aspect, the buffer layer is formed not only on the exposed part of the upper surface of the substrate but also on the upper surface of the mask layer so that the uppermost growth surface of the nitride-based semiconductor layer laterally grown on the mask layer does not come into contact with the mask layer when grown on the buffer layer. Thus, desorption from the outermost growth surface of the nitride-based semiconductor layer hardly takes place, whereby a nitride-based semiconductor layer having a small number of defects can be prepared. Further, the mask layer is directly formed on the substrate so that the nitride-based semiconductor may not be prepared before forming the mask layer, whereby the number of steps of growing the nitride-based semiconductor layer can be reduced. Consequently, a nitride-based semiconductor layer having a small number of dislocations due to lateral growth can be formed through a small number of growth steps. According to the present invention, therefore, a nitride-based semiconductor layer having excellent crystallinity and a small number of dislocations as well as a small number of defects resulting from desorption can be formed through a small number of growth steps.

In the method of preparing a nitride-based semiconductor according to the aforementioned aspect, the mask layer preferably contains a material containing no oxygen atoms. Thus, no oxygen atoms forming the mask layer appear on the surface of the nitride-based semiconductor layer to deteriorate the device characteristics. In this case, the mask layer preferably contains either a nitride or a high-melting point metal. Thus, no oxygen atoms forming the mask layer, containing no oxygen dissimilarly to an SiO₂ film, appear on the surface of the nitride-based semiconductor layer to deteriorate the device characteristics. In this case, the mask layer preferably contains SiN. Thus, a nitride-based semiconductor layer having a smaller number of defects can be prepared from nitrogen (N) atoms forming SiN. In this case, the mask layer may include a multilayer film exposing either the nitride or the high-melting point metal on the outermost surface. Thus, no film such as an SiO₂ film containing oxygen is present on the outermost surface of the mask layer, whereby no oxygen atoms appear on the surface of the nitride-based semiconductor layer to deteriorate the device characteristics.

In the method of preparing a nitride-based semiconductor according to the aforementioned aspect, the mask layer preferably has a striped structure. When the mask layer having a striped structure is employed, the number of coalescence regions between facets is reduced when the nitride-based semiconductor layer is laterally grown, whereby the nitride-based semiconductor layer can be readily planarized. Further, the facets are coalesced along the same direction, to be inhibited from displacement in plane orientation in the coalescence regions.

In the method of preparing a nitride-based semiconductor according to the aforementioned aspect, the upper surface of the substrate and the side surface of the mask layer preferably form a sharp angle. When the upper surface of the substrate and the side surface of the mask layer form a sharp angle, a nitride-based semiconductor layer having excellent crystallinity is formed thereon. In this case, the mask layer may have an inverse trapezoidal shape, or such a shape that the side portion thereof partially projects sideward.

In the method of preparing a nitride-based semiconductor according to the aforementioned aspect, at least a part of the mask layer coming into contact with the substrate preferably has a trapezoidal shape.

The method of preparing a nitride-based semiconductor according to the aforementioned aspect preferably further comprises a step of growing a nitride-based semiconductor element layer having an element region on the nitride-based semiconductor layer. Thus, a nitride-based semiconductor element layer having an element region is grown on the nitride-based semiconductor layer having a small number of defects, whereby a nitride-based semiconductor element having excellent element characteristics can be readily prepared.

A nitride-based semiconductor element according to another aspect of the present invention comprises a mask layer formed on the upper surface of a substrate to partially expose the upper surface of the substrate, a buffer layer formed on the exposed part of the upper surface of the substrate and the upper surface of the mask layer, a nitride-based semiconductor layer formed to cover the buffer layer and a nitride-based semiconductor element layer, formed on the nitride-based semiconductor layer, having an element region.

In the nitride-based semiconductor element according to the aforementioned aspect, the buffer layer is formed not only on the exposed part of the upper surface of the substrate but also on the upper surface of the mask layer so that the outermost growth surface of the nitride-based semiconductor layer laterally grown on the mask layer does not come into contact with the mask layer when the nitride-based semiconductor layer is grown on the buffer layer. Thus, desorption hardly takes place from the outermost growth surface of the nitride-based semiconductor layer, whereby a nitride-based semiconductor layer having a small number of defects can be obtained. Further, the mask layer is directly formed on the substrate so that the nitride-based semiconductor layer may not be formed before formation of the mask layer, whereby the number of growth steps for the nitride-based semiconductor layer can be reduced. Thus, a nitride-based semiconductor layer having a small number of dislocations due to lateral growth can be obtained through a small number of growth steps. When the nitride-based semiconductor element layer having the element region is grown on the nitride-based semiconductor layer having a small number of defects resulting from desorption along with a small number of dislocations, a nitride-based semiconductor element having excellent element characteristics can be readily obtained.

In the nitride-based semiconductor element according to the aforementioned aspect, the mask layer preferably contains a material containing no oxygen atoms. Thus, it is possible to effectively prevent such inconvenience that oxygen atoms forming the mask layer appear on the surface of the nitride-based semiconductor layer to deteriorate the device characteristics. In this case, the mask layer preferably contains either a nitride or a high-melting point metal. Thus, the mask layer contains no oxygen dissimilarly to a film of SiO₂, whereby it is possible to effectively prevent such inconvenience that oxygen atoms forming the mask layer appear on the surface of the nitride-based semiconductor layer to deteriorate the device characteristics. In this case, the mask layer preferably contains SiN. Thus, a nitride-based semiconductor layer having a smaller number of defects can be formed by nitrogen (N) atoms of SiN. In this case, the mask layer may include a multilayer film exposing either the nitride or the high-melting point metal on the outermost surface. Thus, the uppermost surface of the mask layer has no film containing oxygen dissimilarly to a film of SiO₂, whereby no such inconvenience takes place that oxygen atoms appear on the surface of the nitride-based semiconductor layer to deteriorate the device characteristics.

In the nitride-based semiconductor element according to the aforementioned aspect, the mask layer preferably has a striped structure. When such a mask layer having a striped structure is employed, the number of coalescence regions between facets is reduced when the nitride-based semiconductor layer is laterally grown, whereby the nitride-based semiconductor layer can be readily planarized. Further, the facets are coalesced along the same direction, to be inhibited from displacement in plane orientation in the coalescence regions.

In the nitride-based semiconductor element according to the aforementioned aspect, the upper surface of the substrate and the side surface of the mask layer preferably form a sharp angle. When the upper surface of the substrate and the side surface of the mask layer form a sharp angle, a nitride-based semiconductor layer excellent in crystallinity is formed thereon. In this case, the mask layer may have an inverse trapezoidal shape, or such a shape that the side portion thereof partially projects sideward.

In the nitride-based semiconductor according to the aforementioned aspect, at least a part of the mask layer coming into contact with the substrate preferably has a trapezoidal shape.

The foregoing and other objects, features, aspects and advantages of the present invention will become more apparent from the following detailed description of the present invention when taken in conjunction with the accompanying drawings.

### BRIEF DESCRIPTION OF THE DRAWINGS

FIG. 1 is a sectional view for illustrating a method of preparing a nitride-based semiconductor according to an embodiment of the present invention;

FIG. 2 is a perspective view of the step shown in FIG. 1;

FIGS. 3 and 4 are sectional views for illustrating the method of preparing a nitride-based semiconductor according to the embodiment of the present invention;

FIG. 5 is a sectional view showing a semiconductor laser device formed by the method of preparing a nitride-based semiconductor according to the embodiment shown in FIGS. 1 to 4;

FIGS. 6 to 9 are sectional views showing modifications of shapes of mask layers employed for the method of preparing a nitride-based semiconductor according to the embodiment; and

FIGS. 10 to 12 are sectional views for illustrating a conventional method of preparing a nitride-based semiconductor.

### DESCRIPTION OF THE PREFERRED EMBODIMENTS

An embodiment of the present invention is now described with reference to the drawings.

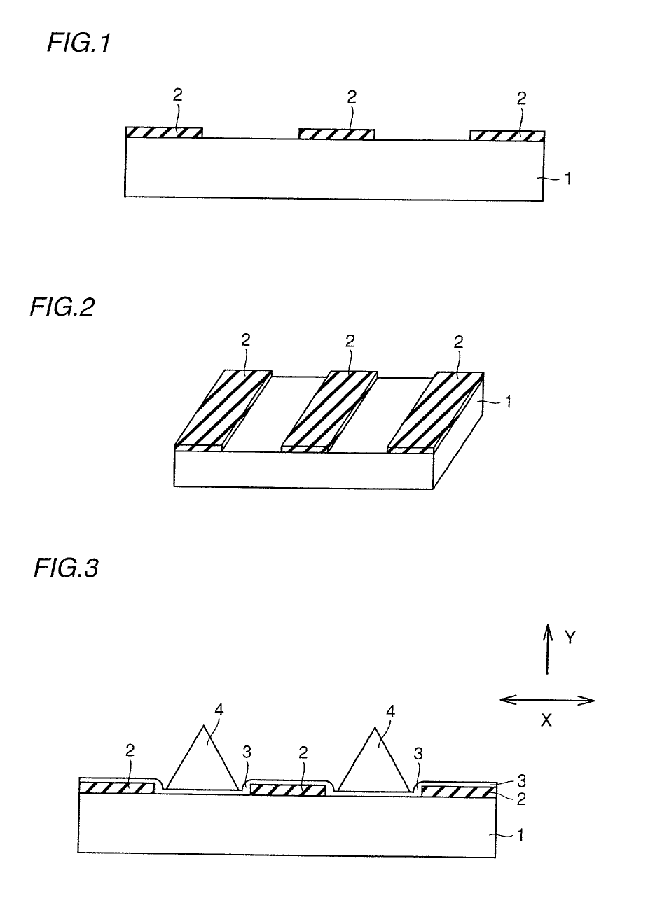

FIGS. 1 to 4 are sectional and perspective view for illustrating a method of preparing a nitride-based semiconductor according to the embodiment of the present invention. The method of preparing a nitride-based semiconductor according to this embodiment is described with reference to FIGS. 1 to 4.

First, mask layers 2 of SiN having a thickness of about 0.1 μm are formed on the C (0001) plane of a sapphire substrate 1 as selective growth masks. A plurality of such mask layers 2 are formed in the form of stripes (striped structure) at a pitch of about 7 μm. More specifically, an SiN film (not shown) is first formed on the overall C plane of the sapphire substrate 1 by plasma CVD (plasma chemical vapor deposition) or electron beam deposition. A striped mask pattern (not shown) of photoresist is formed on the SiN film. The SiN film is partially removed through the mask pattern by wet etching with an HF (hydrofluoric acid) solution or dry etching with CF₄ gas and O₂ gas, thereby forming the striped mask layers 2.

As to the pitch of 7 μm, the widths of regions formed with the mask layers 2 and regions formed with no mask layers 2 may be 2 μm and 5 μm, 3 μm and 4 μm, 4 μm and 3 μm or 5 μm and 2 μm respectively. The widths may alternatively be in other ratios.

Then, an AlₓGaN₁₋ₓ buffer layer 3 (0≦×≦1) having a thickness of about 10 nm to 100 nm (about 0.01 μn to 0.1 μm) is formed on the upper surface of the sapphire substrate 1 formed with the mask layers 2 of SiN by MOCVD (metal organic chemical vapor deposition) or HVPE (hydride vapor phase epitaxy) at a growth temperature of about 500° C. to 700° C. Then, GaN layers 4 are formed by MOCVD or HVPE at a growth temperature of about 1000° C. to 1200° C.

At this time, the AlGaN buffer layer 3 also grows on the mask layers 2 of SiN. In this case, high-temperature growth GaN layers hardly grow on portions of the AlGaN buffer layer 3 located on the mask layers 2 of SiN. Therefore, the high-temperature growth GaN layers selectively grow on portions of the AlGaN buffer layer 3 located on portions of the sapphire substrate 1 exposed between the mask layers 2 of SiN along arrow Y in FIG. 3. Thus, the GaN layers 4 having a facet structure with triangular sections exposing sloping (11-22) planes are formed only on the portions of the AlGaN buffer layer 3 located on the portions of the upper surface of the sapphire substrate 1 exposed between the mask layers 2 of SiN, as shown in FIG. 3.

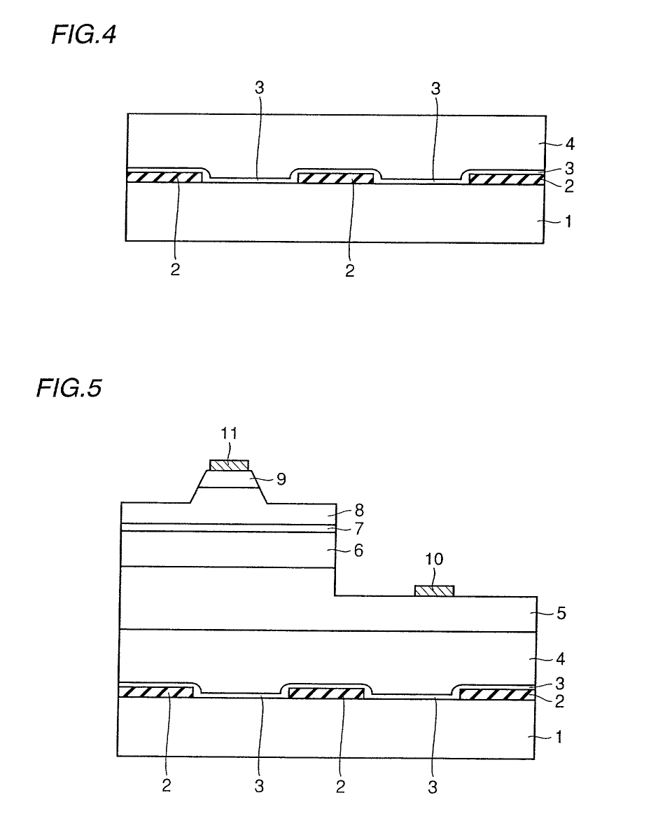

When the growth of the GaN layers 4 further progresses, the GaN layers 4 grow along arrow X (lateral direction) in FIG. 3. The GaN layers 4 extend over the mask layers 2 due to such lateral growth. Finally, the GaN layers 4 of the facet structure coalesce into a continuous film having a flat upper surface, as shown in FIG. 4. According to this embodiment, a GaN layer 4, consisting of a continuous film, having a thickness of about 8 μm is formed with a flat upper surface. This GaN layer 4 is an example of the “nitride-based semiconductor layer” according to the present invention.

According to this embodiment, as hereinabove described, the AlGaN buffer layer 3 is grown not only on the exposed upper surface portions of the sapphire substrate 1 but also on the upper surfaces of the mask layers 2, so that the outermost growth surfaces of the GaN layers 4 laterally grown on the mask layers 2 do not come into contact with the mask layers 2 when the GaN layers 4 are grown on the AlGaN buffer layer 3. Thus, desorption hardly takes place from the outermost growth surfaces of the GaN layers 4, whereby a GaN layer 4 having a small number of defects resulting from desorption can be formed.

According to this embodiment, further, the mask layers 2 are directly formed on the sapphire substrate 1 so that no GaN layers may be formed before formation of the mask layers 2, whereby the number of growth steps for the GaN layers 4 can be reduced. Consequently, the GaN layer 4 having a small number of dislocations by lateral growth can be formed through a small number of growth steps.

According to this embodiment, therefore, a GaN layer 4 having a small number of dislocations as well as a small number of defects resulting from desorption with excellent crystallinity can be formed through a small number of growth steps.

According to this embodiment, further, the mask layers 2 are made of SiN, so that no oxygen atoms forming the mask layers 2 appear on the surfaces of the GaN layers 4 to deteriorate device characteristics dissimilarly to mask layers formed by films of SiO₂ or the like containing oxygen.

According to this embodiment, in addition, the mask layers 2 are formed to have a striped structure for reducing the number of coalescence regions between facets when the GaN layers 4 are laterally grown, whereby the GaN layers 4 can be readily planarized.

FIG. 5 is a sectional view showing a semiconductor laser device fabricated by the aforementioned method of preparing a nitride-based semiconductor according to this embodiment. The structure of and a fabrication process for the semiconductor laser device fabricated by the aforementioned method of preparing a nitride-based semiconductor according to this embodiment are now described with reference to FIG. 5.

In the structure of the semiconductor laser device according to this embodiment, striped mask layers 2 (striped structure) of SiN having a thickness of about 0.1 μm are directly formed on the upper surface of a sapphire substrate 1 at prescribed intervals. An AlGaN buffer layer 3 having a thickness of about 10 nm to 100 nm (about 0.01 μm to 0.1 μm) is formed on upper surface portions of the sapphire substrate 1 located between the mask layers 2 and the upper surfaces of the mask layers 2. A GaN layer 4 of about 8 μm in thickness having a planarized surface is formed on the AlGaN buffer layer 3.

A first conductivity type contact layer 5 of n-type GaN having a thickness of about 4 Mm is formed on the GaN layer 4. A first conductivity type cladding layer 6 of n-type AlGaN having a thickness of about 0.45 μm is formed on the first conductivity type contact layer 5. A multiple quantum well (MQW) active layer 7 of InGaN is formed on the first conductivity type cladding layer 6. A second conductivity type cladding layer 8 of p-type AlGaN having a thickness of about 0.45 μm is formed on the MQW active layer 7. A second conductivity type contact layer 9 of p-type GaN having a thickness of about 0.15 μm is formed on the second conductivity type cladding layer 8. An n-type first conductivity type electrode 10 is formed on an exposed upper surface portion of the first conductivity type contact layer 5. A p-type second conductivity type electrode 11 is formed on the upper surface of the second conductivity type contact layer 9.

The first conductivity type contact layer 5, the first conductivity type cladding layer 6, the MQW active layer 7, the second conductivity type cladding layer 8 and the second conductivity type conduct layer 9 are examples of the “nitride-based semiconductor element layer” according to the present invention.

In order to fabricate the semiconductor laser device according to this embodiment having the aforementioned structure, the mask layers 2 of SiN having a thickness of about 0.1 μm, the AlGaN buffer layer 3 having a thickness of about 10 nm to 100 nm (about 0.01 μm to 0.1 μm) and the GaN layer 4 having a thickness of about 8 μm are successively formed on the sapphire substrate 1 through the method of preparing a nitride-based semiconductor according to this embodiment described with reference to FIGS. 1 to 4.

Then, the first conductivity type contact layer 5 of n-type GaN having a thickness of about 4 μm, the first conductivity type cladding layer 6 of n-type AlGaN having a thickness of about 0.45 μm, the multiple quantum well (MQW) active layer 7 of InGaN, the second conductivity type cladding layer 8 of p-type AlGaN having a thickness of about 0.45 μm and the second conductivity type contact layer 9 of p-type GaN having a thickness of about 0.15 μm are successively formed on the GaN layer 4 by MOCVD, HVPE or gas source MBE (molecular beam epitaxy) employing trimethyl aluminum, trimethyl gallium, trimethyl indium, NH₃, SiH₄ (silane gas) or Cp₂Mg (bis cyclopentadienyl magnesium) as material gas.

The layers from the second conductivity type contact layer 9 to the first conductivity type contact layer 5 are partially etched for exposing a prescribed region of the first conductivity type contact layer 5. The n-type first conductivity type electrode 10 is formed on the exposed prescribed region of the first conductivity type contact layer 5. Further, the p-type second conductivity type electrode 11 is formed on a prescribed region of the second conductivity type contact layer 9.

In the aforementioned semiconductor laser device according to this embodiment, the GaN layer 4 having excellent crystallinity formed by the method of preparing a nitride-based semiconductor according to this embodiment shown in FIGS. 1 to 4 is employed as the underlayer for forming the layers 5 to 9 thereon. As hereinabove described, the AlGaN buffer layer 3 is formed not only on the exposed upper surface portions of the sapphire substrate 3 but also on the upper surfaces of the mask layers 2 so that desorption hardly takes place from the outermost growth surface of the GaN when the GaN layer 4 is laterally grown on the mask layers 2, whereby a GaN layer 4 having a small number of defects resulting from desorption can be formed. Further, the number of dislocations is reduced in the surface of the GaN layer 4 due to the epitaxial lateral overgrowth. Thus, excellent crystallinity can be implemented in the layers 5 to 9 by forming the layers 5 to 9 on the underlayer of the GaN layer 4 having a small number of defects resulting from desorption as well as a small number of dislocations. Thus, a semiconductor laser device having excellent device characteristics as well as high reliability can be obtained according to this embodiment.

Although the present invention has been described and illustrated in detail, it is clearly understood that the same is by way of illustration and example only and is not to be taken by way of limitation, the spirit and scope of the present invention being limited only by the terms of the appended claims.

For example, while the substrate 1 is made of sapphire in the aforementioned embodiment, the present invention is not restricted to this but similar effects can be attained also when an SiC substrate, an Si substrate, a GaAs substrate or a spinel substrate is employed.

While the mask layers 2 are made of SiN in the aforementioned embodiment, the present invention is not restricted to this but similar effects can be attained also when the mask layers 2 are made of a nitride other than SiN or a high melting point metal. In this case, the high melting point preferably has a melting point of at least 1000° C., in particular. Further, the mask layers 2 may be formed by multilayer films exposing a nitride such as SiN or a high melting point metal on the outermost surfaces. Also in this case, the uppermost surfaces of the mask layers 2 include no films containing oxygen such as SiO₂ films, so that no oxygen atoms appear on the surface of the GaN layer 4 to deteriorate the device characteristics.

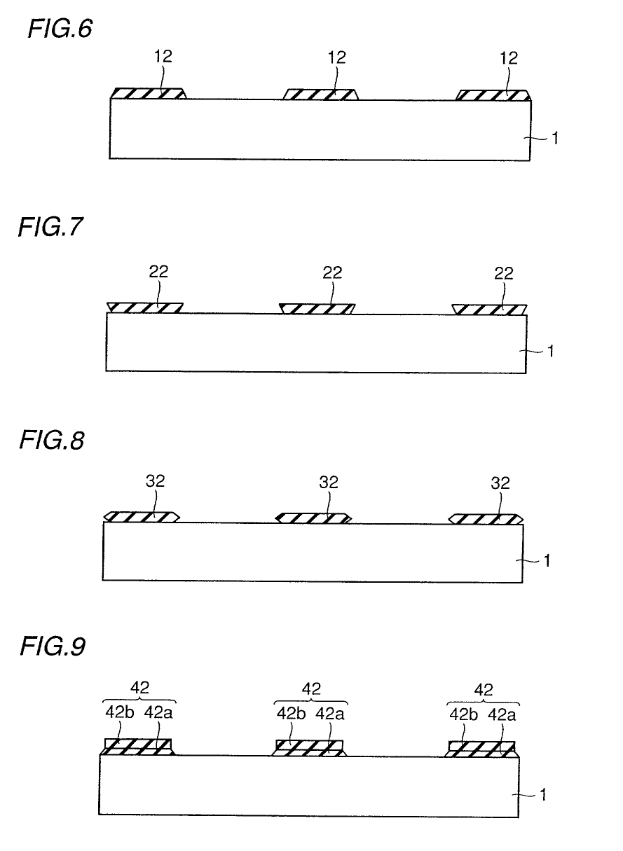

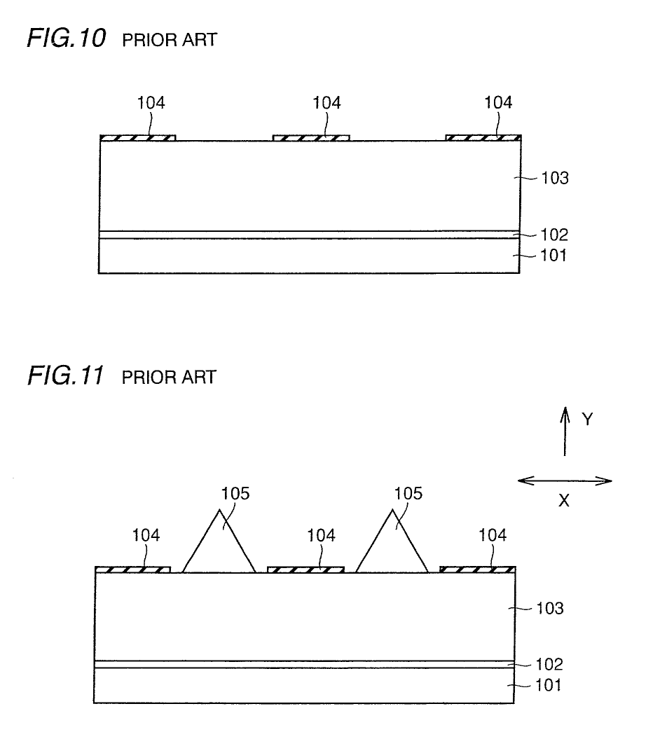

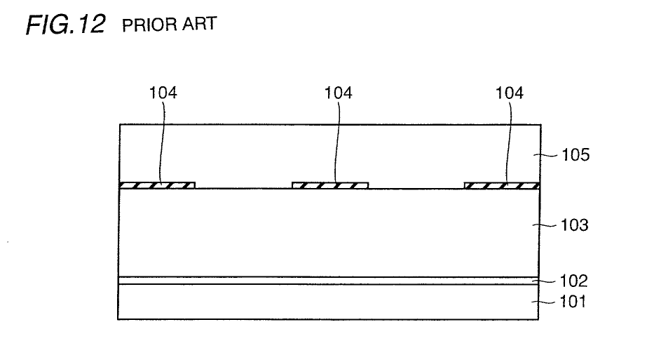

While the mask layers 2 of SiN have rectangular sections as shown in FIG. 1 in the aforementioned embodiment, the present invention is not restricted to this but the mask layers 2 may alternatively have other shapes. For example, trapezoidal mask layers 12 shown in FIG. 6, inverse trapezoidal mask layers 22 shown in FIG. 7 or mask layers 32 having such shapes that side portions thereof partially project sideward as shown in FIG. 8 may be employed. Further, mask layer 42 of a two-layer structure consisting of trapezoidal lower layers 42a and rectangular upper layers 42b may be employed as shown in FIG. 9. Thus, the mask layers may have a multilayer structure. Further alternatively, the mask layers may have a structure obtained by properly combining the structures shown in FIGS. 1 and 6 to 9 with each other. Particularly when the upper surface of the substrate 1 and the mask layers 22 or 32 form a sharp angle as shown in FIG. 7 or 8, a GaN layer (nitride-based semiconductor layer) having excellent crystallinity is formed thereon.

Further, the sapphire substrate (substrate) 1, the AlGaN buffer layer (buffer layer) 3, the GaN layer (nitride-based semiconductor layer) 4 and the respective layers (nitride-based semiconductor element layers) 5 to 9 in the aforementioned embodiment may be prepared from a group III-V nitride-based semiconductor such as GaN (gallium nitride), AlN (aluminum nitride), InN (indium nitride), BN (boron nitride) or TlN (thallium nitride) or a mixed crystal thereof and a group III-V nitride-based semiconductor such as a mixed crystal of any combination of these nitrides containing at least one element of As, P and Sb.

While the AlGaN buffer layer 3 and the GaN layer 4 are doped with no impurity element in the aforementioned embodiment, the present invention is not restricted to this but the AlGaN buffer layer 3 and the GaN layer 4 may alternatively be doped with an n-type impurity, to define first conductivity type layers.

While the mask layers 2 are formed at the pitch of 7 μm in the aforementioned embodiment, the present invention is not restricted to this but the pitch for the mask layers 2 may be other than 7 μm so far as the same is at least 1 μm and not more than 30 μm.

What is claimed is:

1. A method of preparing a nitride-based semiconductor comprising steps of:
forming a mask layer on the upper surface of a substrate to partially expose the upper surface of said substrate;
forming a buffer layer on said exposed part of the upper surface of said substrate and the upper surface of said mask layer; and
thereafter growing a nitride-based semiconductor layer.

2. The method of preparing a nitride-based semiconductor according to claim 1, wherein
said mask layer contains a material containing no oxygen atoms.

3. The method of preparing a nitride-based semiconductor according to claim 2, wherein
said mask layer contains either a nitride or a high-melting point metal.

4. The method of preparing a nitride-based semiconductor according to claim 3, wherein
said mask layer contains SiN.

5. The method of preparing a nitride-based semiconductor according to claim 3, wherein
said mask layer includes a multilayer film exposing either said nitride or said high-melting point metal on the outermost surface.

6. The method of preparing a nitride-based semiconductor according to claim 1, wherein
said mask layer has a striped structure.

7. The method of preparing a nitride-based semiconductor according to claim 1, wherein
the upper surface of said substrate and the side surface of said mask layer form a sharp angle.

8. The method of preparing a nitride-based semiconductor according to claim 7, wherein
said mask layer has an inverse trapezoidal shape.

9. The method of preparing a nitride-based semiconductor according to claim 7, wherein
said mask layer has such a shape that the side portion thereof partially projects sideward.

10. The method of preparing a nitride-based semiconductor according to claim 1, wherein
at least a part of said mask layer coming into contact with said substrate has a trapezoidal shape.

11. The method of preparing a nitride-based semiconductor according to claim 1, further comprising a step of growing a nitride-based semiconductor element layer having an element region on said nitride-based semiconductor layer.

12. A nitride-based semiconductor element comprising:
a mask layer formed on the upper surface of a substrate to partially expose the upper surface of said substrate;
a buffer layer formed on said exposed part of the upper surface of said substrate and the upper surface of said mask layer;
a nitride-based semiconductor layer formed to cover said buffer layer; and
a nitride-based semiconductor element layer, formed on said nitride-based semiconductor layer, having an element region.

13. The nitride-based semiconductor element according to claim 12, wherein
said mask layer contains a material containing no oxygen atoms.

14. The nitride-based semiconductor element according to claim 13, wherein
said mask layer contains either a nitride or a high-melting point metal.

15. The nitride-based semiconductor element according to claim 14, wherein
said mask layer contains SiN.

16. The nitride-based semiconductor element according to claim 14, wherein
said mask layer includes a multilayer film exposing either said nitride or said high-melting point metal on the outermost surface.

17. The a nitride-based semiconductor element according to claim 12, wherein
said mask layer has a striped structure.

18. The nitride-based semiconductor element according to claim 12, wherein
the upper surface of said substrate and the side surface of said mask layer form a sharp angle.

19. The nitride-based semiconductor element according to claim 18, wherein
said mask layer has an inverse trapezoidal shape.

20. The nitride-based semiconductor element according to claim 18, wherein
said mask layer has such a shape that the side portion thereof partially projects sideward.

21. The nitride-based semiconductor according to claim 12, wherein
at least a part of said mask layer coming into contact with said substrate has a trapezoidal shape.
